(19) United States
(12) Patent Application Publication
(10) Pub. No.: US 2003/0065560 A1
(43) Pub. Date: Apr. 3, 2003

(54) Adjusting energy efficiency incentives according to current energy efficiency technology

(75) Inventors: Michael Wayne Brown, Georgetown, TX (US); Rabindranath Dutta, Austin, TX (US); Michael A. Paolini, Austin, TX (US); Newton James Smith JR., Austin, TX (US)

Correspondence Address: Marilyn Smith Dawkins, International Business Machines Corporation, Intellectual Property Law Department, 11400 Burnet Road, Internal Zip 4054, Austin, TX, 78758, US

(73) Assignee: International Business Machines Corporation, Armonk, NY (US)

(21) Appl. No.: 09/969,093

(22) Filed: Oct. 2, 2001

(51) Int. Cl. G06F 17/60; G06F 19/00; G01R 21/00; G01R 21/06; G01R 19/00; G06F 11/30; G06F 15/00; G21C 17/00

(52) U.S. Cl. 705/14; 702/60; 702/64

(57) ABSTRACT

A method, system, and program for adjusting energy efficiency incentives according to current energy efficiency technology are provided. Records of active energy efficiency incentives are maintained, wherein each of the records is maintained in association with a particular product. In response to a change of a standing of one of the products in relation to current energy efficiency technology, an associated active energy efficiency incentive is adjusted, such that purchase of the current energy efficiency technology is promoted.

### CROSS-REFERENCE TO RELATED APPLICATIONS

The present application is related to the following co-pending applications, incorporated herein by reference:

(1) U.S. patent application Ser. No. ___/______ (Attorney Docket No. AUS920010695US1);

(2) U.S. patent application Ser. No. ___/______ (Attorney Docket No. AUS920010696US1);

(3) U.S. patent application Ser. No. ___/______ (Attorney Docket No. AUS920010697US1)

(4) U.S. patent application Ser. No. ___/______ (Attorney Docket No. AUS920010698US1);

(5) U.S. patent application Ser. No. ___/______ (Attorney Docket No. AUS920010699US1);

(6) U.S. patent application Ser. No. ___/______ (Attorney Docket No. AUS920010700US1);

(7) U.S. patent application Ser. No. ___/______ (Attorney Docket No. AUS92001071US1);

(8) U.S. patent application Ser. No. ___/______ (Attorney Docket No. AUS920010702US1);

(9) U.S. patent application Ser. No. ___/______ (Attorney Docket No. AUS920010705US1);

(10) U.S. patent application Ser. No. ___/______ (Attorney Docket No. AUS920010706US1);

(11) U.S. patent application Ser. No. ___/______ (Attorney Docket No. AUS920010707US1); and

(12) U.S. patent application Ser. No. ___/______ (Attorney Docket No. AUS920010708US1).

### BACKGROUND OF THE INVENTION

1. Technical Field

The present invention relates in general to computer systems and, in particular, to conservation of energy facilitated by computer systems. Still more particularly, the present invention relates to adjusting energy efficiency incentives according to current energy efficiency technology.

2. Description of the Related Art

Conservation of energy, water, and other resources is of interest globally as resources become more scarce and expensive. More conservative processes for producing products continue to be created. In addition, recyclable products with special markings continue to surface in the consumer world. However, regardless of whether a product is made by a more conservative process, is recyclable, or is enabled for use in a more conservative manner, energy resources are still utilized in association with the manufacture and use of the product.

Several energy efficiency standards have been designated by government bodies, government agencies and non-governmental organizations as benchmarks of energy efficiency and as standards for identifying energy efficient products. For example, Corporate Average Fuel Economy Standards (CAFÉ) indicate energy efficiency standards for vehicles, including a preferred miles per gallon of vehicles depending on the type of vehicle. As another example, Energy Star ratings designate building energy efficiency standards. In addition, an Energy Star label is placed on products that meet Energy Star ratings for energy efficient products.

However, while energy efficient products are available and continue to be improved, consumers continue to use old products, rather than replacing old, inefficient products with newer, more efficient products. Typically, consumers may not choose to replace old products because the cost of maintaining and using the old product is less than purchasing a new product, even with the monthly resource usage savings due to energy efficiency.

Some governments and organizations encourage consumers to replace old, inefficient products with newer, more efficient products by providing a rebate for a portion of the purchase price of newer, more efficient products. However, with the initial cost of appliances, heating and cooling systems, and other energy efficiency products, the amount of the rebate typically does not render the newer product more economical over the old product.

Further, energy efficiency standards rapidly change as research shows changes in the environment due to product manufacture. In addition, technology developments that make products capable of greater efficiencies propel energy efficiency standards to change, to reflect new efficiency abilities.

With changes in energy efficiency standards, products that were considered energy efficient a short period of time ago, may become outdated according to energy efficiency standards. Where a consumer purchases an energy efficient product according to one set of standards and that set of standards changes before the product has become outdated or has shown signs of decrease in energy efficiency, there is even less incentive for that consumer to upgrade to more energy efficient products as standards change.

In addition, when consumers do purchase replacement or new products, consumers are often driven by an initial price. Initially, less energy efficiency products may cost less than energy efficient products, therefore making it difficult to change consumer habits to select more energy efficient and environmentally safe products. In addition, where different brands and models of a product, such as a dishwasher, are comparable in cost, consumers are likely to choose a brand of product that has been successful before, rather than selecting a product based on energy efficiency.

Therefore, in view of the foregoing, it would be advantageous to provide a method, system, and program for promoting the purchase of products including the most current energy efficiency technologies.

### SUMMARY OF THE INVENTION

In view of the foregoing, it is therefore an object of the present invention to provide an improved computer system.

It is another object of the present invention to provide a business method, system and program for conservation of energy facilitated by computer systems.

It is yet another object of the present invention to provide a business method, system and program for adjusting energy efficiency incentives according to current energy efficiency technology are provided.

According to one aspect of the present invention, records of active energy efficiency incentives are maintained, wherein each of the records is maintained in association with a particular product. In response to a change of a standing of one of the products in relation to current energy efficiency technology, an associated active energy efficiency incentive is adjusted, such that purchase of the current energy efficiency technology is promoted.

All objects, features, and advantages of the present invention will become apparent in the following detailed written description.

### BRIEF DESCRIPTION OF THE DRAWINGS

The novel features believed characteristic of the invention are set forth in the appended claims. The invention itself however, as well as a preferred mode of use, further objects and advantages thereof, will best be understood by reference to the following detailed description of an illustrative embodiment when read in conjunction with the accompanying drawings, wherein:

FIG. 1 depicts one embodiment of a computer system with which the method, system and program of the present invention may advantageously be utilized;

FIG. 2 illustrates a simplified block diagram of a client/server environment in which promoting and controlling energy conservation may be performed in accordance with the method, system and program of the present invention;

FIG. 3 depicts a block diagram of multiple types of servers and clients that may be utilized to promote and control energy incentives for energy efficient product purchases in accordance with the method, system, and program of the present invention;

FIG. 4 illustrates a block diagram of a conservative product incentive system in accordance with the method, system, and program of the present invention;

FIG. 5 depicts a block diagram of a product with multiple energy factors in accordance with the method, system, and program of the present invention;

FIG. 6 illustrates a block diagram of energy factor cost standards in accordance with the method, system and program of the present invention;

FIG. 7 depicts a high level logic flowchart of a process and program for requesting product incentives in accordance with the method, system, and program of the present invention;

FIG. 8 illustrates a high level logic flowchart of a process and program for determining product incentives for efficient products in accordance with the method, system, and program of the present invention; and

FIG. 9 depicts a high level logic flowchart of a process and program for adjusting incentives for a product in accordance with the method, system, and program of the present invention.

### DETAILED DESCRIPTION OF THE PREFERRED EMBODIMENT

A method, system, and program for promoting use of the most current energy efficiency technology is provided. In particular, energy efficiency incentives are utilized to promote use of the most current energy efficiency technology. For purposes of the present invention, incentives may include, but are not limited to, credits, rebates, tax rebates, electronic coupons, and other forms of monetary compensation. Advantageously, in the present invention, incentives may be transferred as redeemable electronic payments. Further, incentives may be applied at the point of purchase, at a point after the point of purchase, or over a period of time. Incentives that have been distributed, but not applied, are considered active. In addition, incentives that are applied over a period of time are considered active until the lifetime of the incentive expires. Further, active incentives may be adjusted according to changes in current energy efficient technology, decline in the energy efficiency of a product for which the active incentive is available, and maintenance and service of that product.

Energy factors may include resources required to produce the product, resources required to use the product, and resources required to dispose of the product. Resources may include, but are not limited to, natural resources, utility resources, air, land, non-recyclable products, and other consumable products.

In the following description, for the purposes of explanation, numerous specific details are set forth to provide a thorough understanding of the present invention. It will be apparent, however, to one skilled in the art that the present invention may be practiced without these specific details. In other instances, well-known structures and devices are shown in block diagram form to avoid unnecessarily obscuring the present invention.

### Hardware Overview

The present invention may be executed in a variety of systems, including a variety of computing systems and electronic devices under a number of different operating systems. In one embodiment of the present invention, a computing system may include a portable computing system such as a notebook computer, a palmtop computer, a personal digital assistant, a telephone or other electronic computing system that may also incorporate communications features that provide for telephony, enhanced telephony, messaging and information services. However, computing systems may also include, for example, a desktop computer, a network computer, a midrange computer, a server system or a mainframe computer. Therefore, in general, the present invention is preferably executed in at least one computer system that performs computing tasks such as manipulating data in storage that is accessible to the computer system. In addition, the at least one computer system preferably includes at least one output device and at least one input device.

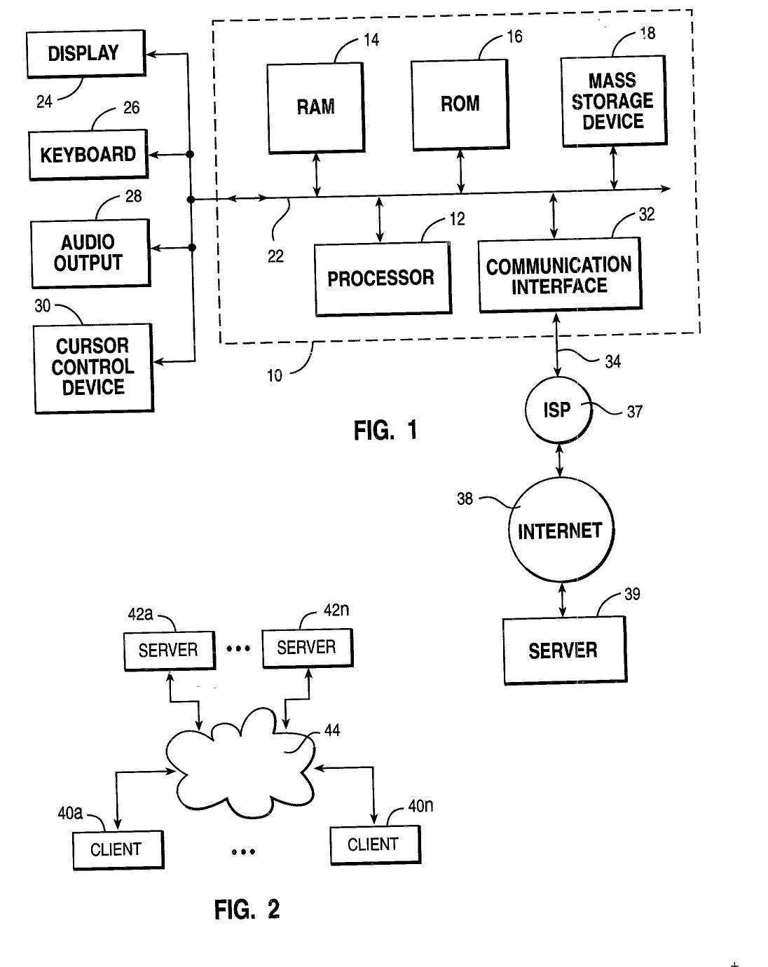

Referring now to the drawings and in particular to FIG. 1, there is depicted one embodiment of a computer system with which the method, system and program of the present invention may advantageously be utilized. Computer system 10 comprises a bus 22 or other communication device for communicating information within computer system 10, and at least one processing device such as processor 12, coupled to bus 22 for processing information. Bus 22 preferably includes low-latency and high-latency paths that are connected by bridges and controlled within computer system 10 by multiple bus controllers.

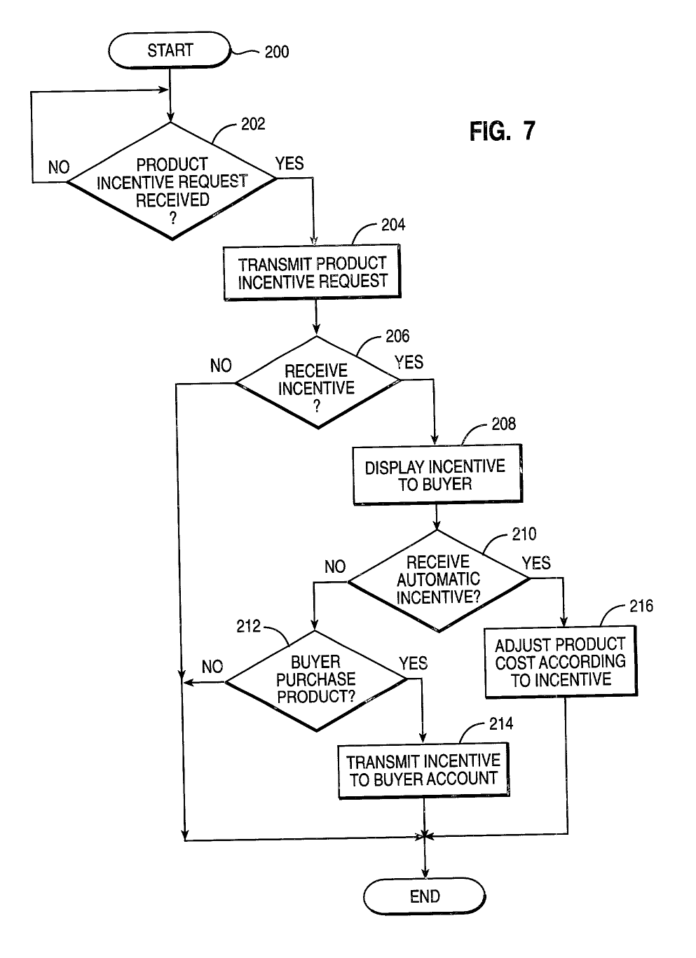

Processor 12 may be a general-purpose processor such as IBM's PowerPC™ processor that, during normal operation, processes data under the control of operating system and application software stored in a dynamic storage device such as random access memory (RAM) 14 and a static storage device such as Read Only Memory (ROM) 16. The operating system preferably provides a graphical user interface (GUI) to the user. In a preferred embodiment, application software contains machine executable instructions that when executed on processor 12 carry out the operations depicted in the flowcharts of FIGS. 7, 8, 9 and others described herein. Alternatively, the steps of the present invention might be performed by specific hardware components that contain hardwire logic for performing the steps, or by any combination of programmed computer components and custom hardware components.

The present invention may be provided as a computer program product, included on a machine-readable medium having stored thereon the machine executable instructions used to program computer system 10 to perform a process according to the present invention. The term “machine-readable medium” as used herein includes any medium that participates in providing instructions to processor 12 or other components of computer system 10 for execution. Such a medium may take many forms including, but not limited to, non-volatile media, volatile media, and transmission media. Common forms of non-volatile media include, for example, a floppy disk, a flexible disk, a hard disk, magnetic tape or any other magnetic medium, a compact disc ROM (CD-ROM) or any other optical medium, punch cards or any other physical medium with patterns of holes, a programmable ROM (PROM), an erasable PROM (EPROM), electrically EPROM (EEPROM), a flash memory, any other memory chip or cartridge, or any other medium from which computer system 10 can read and which is suitable for storing instructions. In the present embodiment, an example of non-volatile media is storage device 18. Volatile media includes dynamic memory such as RAM 14. Transmission media includes coaxial cables, copper wire or fiber optics, including the wires that comprise bus 22. Transmission media can also take the form of acoustic or light waves, such as those generated during radio wave or infrared data communications.

Moreover, the present invention may be downloaded as a computer program product, wherein the program instructions may be transferred from a remote computer such as a server 39 to requesting computer system 10 by way of data signals embodied in a carrier wave or other propagation medium via a network link 34 (e.g., a modem or network connection) to a communications interface 32 coupled to bus 22. Communications interface 32 provides a two-way data communications coupling to network link 34 that may be connected, for example, to a local area network (LAN), wide area network (WAN), or as depicted herein, directly to an Internet Service Provider (ISP) 37. In particular, network link 34 may provide wired and/or wireless network communications to one or more networks.

ISP 37 in turn provides data communication services through the Internet 38 or other network. Internet 38 may refer to the worldwide collection of networks and gateways that use a particular protocol, such as Transmission Control Protocol (TCP) and Internet Protocol (IP), to communicate with one another. ISP 37 and Internet 38 both use electrical, electromagnetic, or optical signals that carry digital or analog data streams. The signals through the various networks and the signals on network link 34 and through communication interface 32, which carry the digital or analog data to and from computer system 10, are exemplary forms of carrier waves transporting the information.

Further, multiple peripheral components may be added to computer system 10. For example, an audio output 28 is attached to bus 22 for controlling audio output through a speaker or other audio projection device. A display 24 is also attached to bus 22 for providing visual, tactile or other graphical representation formats. A keyboard 26 and cursor control device 30, such as a mouse, trackball, or cursor direction keys, are coupled to bus 22 as interfaces for user inputs to computer system 10. In alternate embodiments of the present invention, additional input and output peripheral components may be added.

### Networking Overview

With reference now to FIG. 2, there is depicted a simplified block diagram of a client/server environment in which promoting and controlling energy conservation may be performed in accordance with the method, system and program of the present invention. The client/server environment is implemented within multiple network architectures. For example, the architecture of the World Wide Web (the Web) follows a traditional client/server modeled environment.

The terms “client” and “server” are used to refer to a computer's general role as a requester of data (the client) or provider of data (the server). In the Web environment, web browsers such as Netscape Navigator typically reside on client system 40a-40n and render Web documents (pages) served by server systems 42a-42n. Additionally, each of client systems 40a-40n and server systems 42a-42n may function as both a “client” and a “server” and may be implemented utilizing a computer system such as computer system 10 of FIG. 1.

The Web may refer to the total set of interlinked hypertext documents residing on servers all around the world. Network 44, such as the Internet, provides an infrastructure for transmitting these hypertext documents between server systems 42a-42n and client systems 40a-40n. Documents (pages) on the Web may be written in multiple languages, such as Hypertext Markup Language (HTML) or Extensible Markup Language (XML), and identified by Uniform Resource Indicators (URIs) that specify the particular server and pathname by which a file can be accessed, and then transmitted from that server to an end user utilizing a protocol such as Hypertext Transfer Protocol (HTTP). Web pages may further include text, graphic images, movie files, and sounds as well as Java applets and other small embedded software programs that execute when the user activates them by clicking on a link.

It is advantageous in the present invention to utilize both wireless and wired network connections to network 44. Wireless network connections may be implemented utilizing Bluetooth™, other short or long distance radio frequency broadcasting or infrared transmissions. Advantageously, whether wireless or wired network connections are utilized, multiple types of encryption security features may be utilized to protect transmission of product incentives, as will be understood by one skilled in the art.

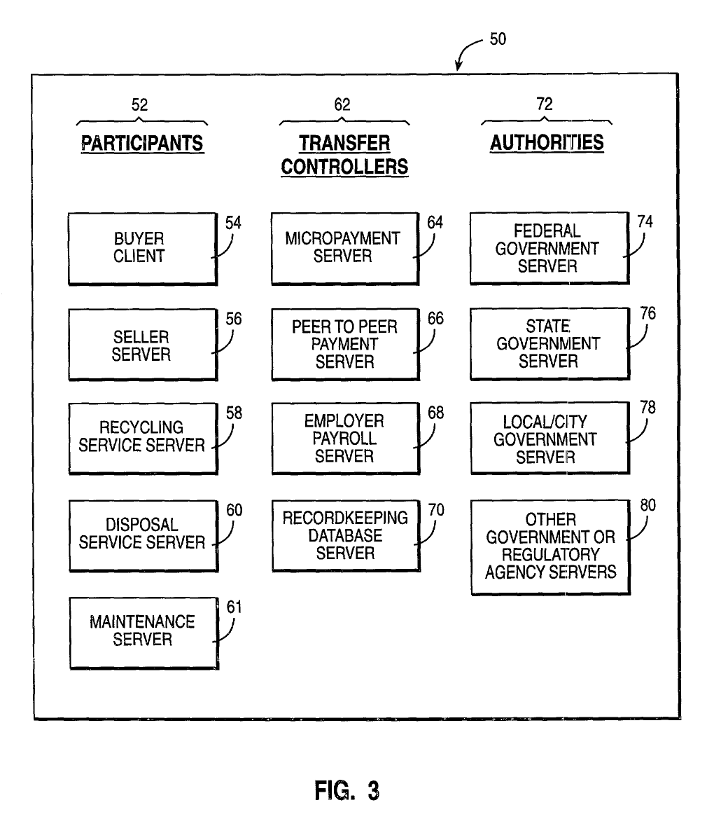

Referring now to FIG. 3, there is depicted a block diagram of multiple types of servers and clients that may be utilized to promote and control energy incentives for energy efficient product purchases in accordance with the method, system, and program of the present invention. As illustrated, multiple client and server elements 50 are divided according to category. In the present embodiment categories include, but are not limited to, participants 52, transfer controllers 62, and authorities 72.

Participants 52 advantageously include all levels of individuals, business, and corporations involved in energy conservation. In the present embodiment, participants 52 include, but are not limited to, a buyer client 54, a retailer server 56, a recycling service server 58, a disposal service server 60, and a maintenance server 61. Advantageously, in the present invention emphasis is placed on product incentives being distributed to buyers, however product incentives may also be provided to retailers, distributors, and manufacturers to encourage purchase, sale, and manufacture of more energy efficient products. Further, participants may include recycling and disposal centers that receive products for recycle or disposal and may return incentives to buyers for recycling particular products or disposing of particular products in a conservative manner. Therefore, advantageously, incentives may be included for proper recycling of a product to reduce the illegal dumping of harmful products.

Transfer controllers 62 advantageously include all levels of controllers that may be provided for transferring and holding monetary amounts in response to conservation or lack of conservation by at least one of participants 52. In the present embodiment, transfer controllers 62 include, but are not limited to, a micropayment server 64, a peer-to-peer payment server 66, an employer payroll server 68, and a recordkeeping database server 70. In the present invention, product incentives may be transferred to and between any of transfer controllers 62 in the form of an electronic payment, coupon, or record. In the present invention, transfer controllers 62 may be incorporated within a participants system.

In particular, micropayment server 64 includes internal electronic payments that may be redeemed for products provided by the authority giving the product incentive. Peer-to-peer payment server 66 includes external electronic payments that may be redeemed for products and services external to the authority giving the product incentive. Employer payroll server 68 tracks employee pay and may adjust pay according to any pre-tax product incentives. Recordkeeping database server 70 tracks a record of all product incentives distributed.

Authorities 72 advantageously include all levels of government and policy setting groups that may be responsible for setting policy and standards to determine product incentives in response to conservation or lack of conservation by at least one of participants 52. In the present example, authorities 72 specifically includes federal government (govt) server 74, state government server 76, local/city government server 78, and other government or regulatory agency servers 80. Advantageously, in the present invention, any of authorities 72 may designate energy factor cost requirements from which product incentives may be determined. The present invention is particularly advantageous where governments may designate energy factor cost requirements for receipt of tax rebates, such that a particular government may provide tax incentives for a particular type of conservation.

### Product Incentives Context

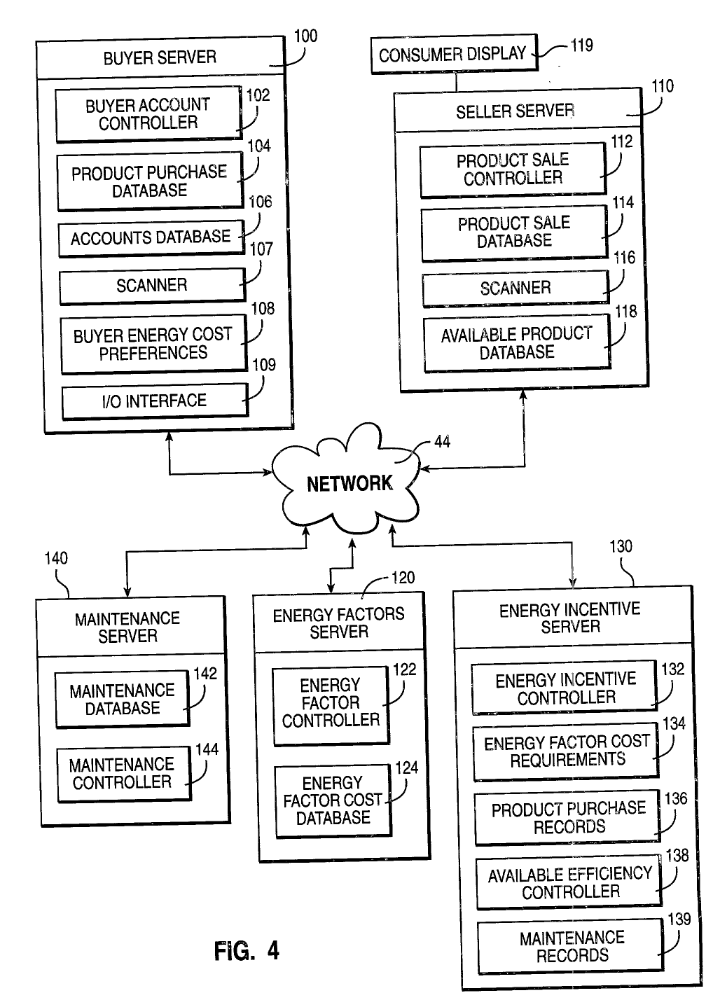

With reference now to FIG. 4, there is depicted a block diagram of a conservative product incentive system in accordance with the method, system, and program of the present invention. As illustrated, multiple systems are communicatively connected via network 44.

A seller server 110 may include a product sale controller 112, a product sale database 114, and a scanner 116. Scanner 116 preferably detects an identifier for a product. Scanner 116 may utilize multiple scanning methods as will be understood by one skilled in the art. For example, scanning methods may include a scan of a UPC symbol, a scan of an alpha numerical identifier, a scan of a magnetic strip, and other scannable surfaces. In addition, a product identifier may be input to seller server 110 through other available input devices.

Scanned product identifiers are preferably stored in product sale database 114 when the product is purchased. Product sale controller 112 controls the display and calculation of sales of products according to the scanned product identifiers and incentives received therewith, as will be further described. Costs of products with or without incentives may be displayed to each buyer at a display, such as consumer display 119.

According to one embodiment of the present invention, a product identifier is transmitted from seller server 110 to energy factors server 120. An energy factor cost database 124 is searched with the product identifier by an energy factor controller 122 to determine the energy factors associated with the product identifier and the costs associated with those energy factors. The energy factor costs are then transmitted to an energy incentive server 130. In addition, energy factors and energy factor costs may be transmitted to seller server 110 for display via consumer display 119 and/or transmitted to buyer server 100 to be displayed via I/O interface 109.

An energy factor cost requirements database 134 within energy incentive server 130 is searched according to the energy factor costs by an energy incentive controller 132. An incentive for the product is determined by comparing the energy factor costs with energy factors cost requirements database 134. The incentive may be in the form of a credit, a rebate, a voucher, a tax rebate, or other monetary incentive that is transmittable as an electronic payment from energy incentive server 130. The incentive for the product is then transmitted to seller server 110 to display to a buyer in association with a particular product. In addition, a record of the incentive according to the consumer purchase is stored in product purchase records database 136.

According to one advantage of the present invention, seller server 110 may pre-request incentives for available products according to product identifiers, such that the incentives for available products are transmitted to a seller as an electronic payment to be passed on to a buyer when the available products are purchased. Such pre-requested incentives are advantageously stored with product identifiers in an available product database 118. Advantageously, current incentives may also be displayed on an electronic display with products via a consumer display 119. For example, an electronic price display may include current incentive amounts.

In order to complete a purchase of a product, a buyer may provide a buyer identifier to seller server 110 via input devices including, but not limited to, a smart card reader, a credit card reader, or other electronic reader. From the buyer identifier, a buyer server 100 may be accessed by seller server 110 with a request to purchase a product.

Buyer server 100 preferably includes a buyer account controller 102 that receives product purchase requests from seller server 110 and controls reduction of the purchase request amount from an accounts database 106 associated with the buyer identifier. In addition, a record of the product identifiers within the product purchase request is preferably stored in a product purchase database in association with the buyer identifier.

According to one advantage of the present invention, buyer server 100 may also include buyer energy cost preferences 108 in association with a buyer identifier. In particular, energy cost preferences 108 may include preferred types of energy factors and ranges of preferred costs for energy factors.

A buyer may request to search products that are available from a seller according to the preferences in buyer energy cost preferences 108. An available product database 118 may be searched in response to a request by the buyer to search products that are available from seller server 110 according to buyer preferences. An input/output (I/O) interface 109 enables the buyer to specify search requests and enables buyer server 100 to output products meeting the specified search requests.

Advantageously, for each product, a manufacturer or other organization will determine energy factors for that product and the cost of those energy factors. Energy factor costs are then stored in energy factor cost database 124. Alternatively, energy factor costs may be stored in alternate server systems and a reference to those server system locations stored in energy factor cost database 124. For example, individual product manufacturers may maintain independent energy factor costs for products.

According to one embodiment of the present invention, an energy factor may be specified as a type of energy standard that may be estimated for the use of a product. Then, the energy factor cost is the rating within that energy standard for the product. For example, an air conditioning unit may have an energy factor of a seasonal energy efficiency rating (SEER) rating. The energy factor cost would be the actual rating, such as an 8, associated with the energy factor.

According to another embodiment of the present invention, an energy factor may represent the disposal of a product, where the energy factor cost is a cost that has been added to the purchase price of a product, but which may be redeemed to the consumer as an incentive for proper disposal of the product. Alternatively, the disposal energy factor may be utilized to determine an incentive for proper disposal, independent of the original purchase price. Proper disposal may include disposal within a particular time period, at a particular location, utilizing a particular procedure, and other disposal requirements.

According to yet another embodiment of the present invention, an energy factor may indicate the types of manufacturing processes utilized. The energy factor cost then indicates the cost to the environment of each of the manufacturing processes. In addition, manufacturing energy factors may be further specified according to cost of materials, labor, resources, disposal, and other manufacturing factors.

Referring now to energy incentive server 130, energy factor cost requirements database 134 may be designated by an authority, such as a government or other policy setting organization. For example, a local government may provide incentives for purchase of particular types of recyclable products that include an energy factor cost for recycling below a particular amount.

In addition to providing incentives at the point of purchase, another advantage of the present invention is in the adjustment of incentives according to a product efficiency in comparison with current technology, decline in actual efficiency of products, and maintenance of products. An available efficiency controller 138 advantageously controls adjustment of energy factor cost requirements and other incentive standards.

In order to adjust incentives according to a product efficiency in comparison with current technology, energy factor cost requirements 134 are preferably maintained in a tiered scale that adjusts according to increases in available energy efficiency technology. Available efficiency controller 138 advantageously monitors currently available energy efficiencies and adjusts energy factor cost requirements 134 accordingly.

For example, in dishwasher technology, a first technology may be developed that meets a first set of energy efficiency standards. However, a second technology may be developed a year later that improves the energy efficiency of a dishwasher.

Advantageously, energy factor cost requirements 134 are adjusted such that when the first technology is introduced, a larger incentive is provided to consumers to purchase that technology, however when the second technology is introduced, the incentive for purchasing the first technology is reduced, such that purchase of the second, more efficient technology will be promoted.

Where a long-term active incentive is provided with the purchase of a product, as energy factor cost requirements 134 are adjusted according to current technology, the long-term active incentive may also adjust according to the current incentive rate. For example, a long term incentive may provide a reduction in a periodic charge, such as a reduction in an energy usage fee. As the relative energy efficiency of the product decreases in comparison with current energy efficiency technology, the incentive may also be reduced. The result of adjusting long-term incentives is promotion of continual upgrades to the most energy efficient product solutions.

In addition to energy factor cost requirements 134 adjusting over time, the actual efficiency of a product may adjust over time. Available efficiency controller 138 therefore monitors the expected energy efficiencies for products and the decline in those efficiencies, as indicated by a manufacturer or other authority. Available efficiency controller 138 filters product purchase records 136 according to the declines in efficiency and may adjust long-term active incentives according to declines in efficiency or may adjust an energy usage rate or other cost to a consumer to promote purchase of a more energy efficient product. For example, as the actual energy efficiency of a product declines, the rate that a consumer is charged for a resource utilized by that product may increase, to promote purchase of a more energy efficient product.

According to another advantage of the present invention, a maintenance server 140 advantageously monitors maintenance and servicing of products, where available. A maintenance database 142 stores maintenance and service records according to product and consumer. A maintenance controller 144 controls verification, storage, and distribution of maintenance records.

Preferably, where a consumer maintains or services a product to maintain or improve the energy efficiency achievable by the product, an incentive is provided. Therefore, maintenance server 140 transfers maintenance records to energy incentive server 130, where the maintenance records are stored in maintenance records database 139. Available efficiency controller 138 compares the estimated efficiency of a product with the maintenance performed according to a maintenance record with energy factor cost requirements 134. An incentive is determined according to the relative energy efficiency of the product with the maintenance performed. The incentive may then decrease as the energy efficiency of the product decreases or as energy efficiency technology increases.

In particular, it is advantageous with some products to promote maintenance and service of a product in order maintain or increase the energy efficiency. In particular, products requiring a large initial investment or non-recyclable products are more advantageously maintained and serviced for a period of time. Where incentives are provided for replacement of individual parts within products, consumers will demand replacement parts that increase energy efficiency without requiring purchase of a new appliance. Therefore, manufacturers will have an increasing consumer base to produce appliances and other products that are compartmentalized, such that as energy efficiency technology improves, parts of an appliance may be replaced, rather than the whole appliance.

In addition to energy factor cost requirements being adjusted over time, the energy factor costs associated with individual products by energy factor server 120 may adjust over time according to the actual energy efficiencies achieved by individual products. Advantageously, resource usage by individual products may be monitored utilizing systems such as X10 and other individual system monitoring systems. Actual resource usage information received by energy factors server 120 may be utilized by energy factor controller to adjust the actual energy factor costs for an individual product within energy factor cost database 124. Monitoring actual efficiencies allows declines in efficiencies to be based on actual declines in efficiency, rather than estimated declines.

Further, monitoring actual efficiencies of a product is particularly advantageous where, for example, a used product is being sold. The lifetime of the product is preferably tracked and adjustments made for declines in actual energy efficiency by increasing energy factor costs for the product. An incentive for purchasing the used product is then calculated based on the actual energy factor costs.

While in the present embodiment energy factors server 120 and energy incentive server 130 are depicted as independent server systems, in alternate embodiments energy factors server 120 and energy incentive server 130 may be incorporated within a single server system. Further, while in the present embodiment energy factor cost database 124 is searched for energy factor costs for each product identifier, in alternate embodiments, energy factor costs may be included in the data comprising a product identifier.

According to a further advantage of the present invention, in one embodiment buyer server 100 is a handheld, palm-top, or other easily transportable computer system. A scanner 107 scans a product identifier from the product packaging or other scannable surface. Buyer server 100 then transmits the scanned product identifier to energy factors server 120 with a request for an energy factor cost breakdown for the product. Energy factors server 120 preferably returns the energy factor cost breakdown for the product, which is displayed to the consumer via I/O interface 109. Display of returned energy factor cost breakdowns may be further specified according to buyer energy cost preferences 108. For example, the portions of an energy factor cost breakdown that do not meet buyer energy cost preferences 108 may be displayed in a subdued manner in comparison with those portions of the energy factor cost breakdown that do meet buyer energy cost preferences 108. Further, in displaying energy factor cost breakdowns, preferably any icons that are associated with particular types of energy efficiency may be displayed to visually indicate the energy rating of each energy factor of a product.

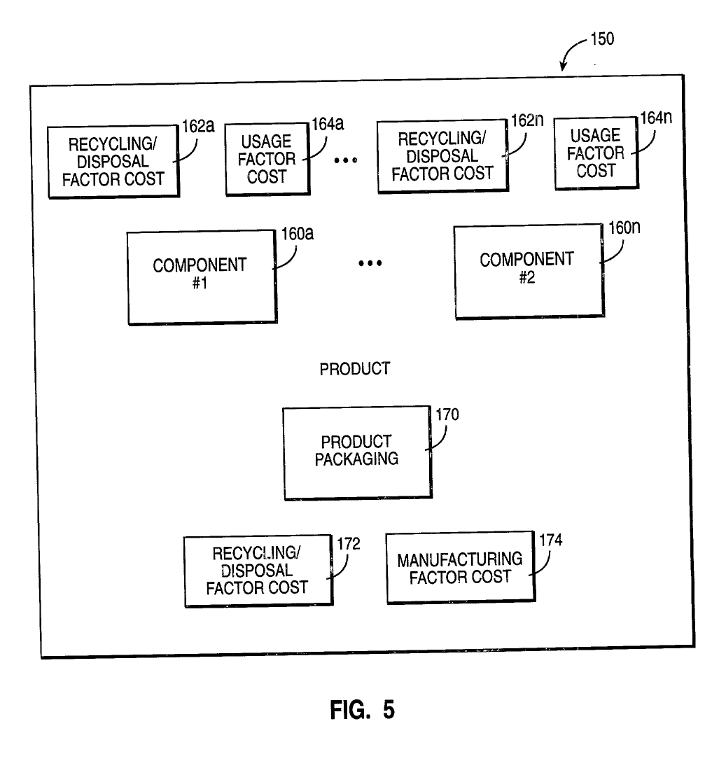

Referring now to FIG. 5, there is illustrated a block diagram of a product with multiple energy factors in accordance with the method, system, and program of the present invention.

As depicted, a product 150 includes multiple components 160a-160n. Each of components 160a-160n preferably is distinguishable according to multiple energy factors with associated costs.

In the present example, each of components 160a-160n is divided into recycling and/or disposal factors 162a-162n and usage factors 164a-164n. A cost is associated with the energy associated with each of the factors. The cost may be a monetary amount or a value that represents a resource cost, for resources such as the air for which a bill is not received. In alternate embodiments, additional factors, such as manufacturing and shipping may be included where those factors add to the energy utilized by a product.

As an example, a product, such as a car, may include multiple engine components. For example, engine components may include a battery and an oil filter. The battery may include multiple energy factors, such as the materials to produce a battery, the energy required to produce the battery, and the energy utilized to dispose of the battery. The oil filter may include multiple energy factors such as the material to make the oil filter, the energy utilized to produce the oil filter and the energy utilized to dispose of the oil filter.

In addition, in the present example, energy factors of recycling and/or disposal 172 or manufacturing 174 may be associated with product packaging 170. Many products utilize superfluous packaging that is costly both in production and in energy consumption. Where a manufacturer utilizes more energy efficient packaging for a product, consumers should be given an incentive to purchase the energy efficient packaged product.

Focusing on recycling and disposing costs, the cost of a product may include a deposit on the product, where if the consumer returns the product and/or packaging of the product for recycling, then the consumer is given the deposit in return. According to the present invention, the recycling deposit cost of packaging or another component of product 150 may be included in recycling and/or disposal factor costs 162a-162n and 172. Recycling centers may detect the product identifier, transmit the product identifier with a request for an deposit or other recycling incentive, and then provide the person recycling with the deposit incentive if returned.

Usage factors costs 164a-164n may include an actual cost for usage or an estimated cost for usage of a refrigerator over a year's time. In addition, usage factor costs 164a-164n may include energy efficiency ratings that indicate the energy efficiency of the product based on a particular scale. For example, an appliance may be rated as an Energy Star™ appliance.

In particular, energy costs assigned to energy factors may be variable depending on actual usage. For example, a vehicle may have a first usage cost if one person is utilizing the vehicle and a second usage cost if four people are utilizing the vehicle to reward filling more seats in the vehicle, even though the fuel efficiency may decrease slightly with more weight in the vehicle.

In addition, energy costs assigned to energy factors may be variable depending on the estimated decline in energy efficiency of a product over time. For example, usage factor costs 164a-164n may decrease over time as the estimated energy efficiency for a product declines. In addition, other costs, such as a recycling cost or disposal cost may increase or decrease depending on the current cost to recycle or dispose of the product.

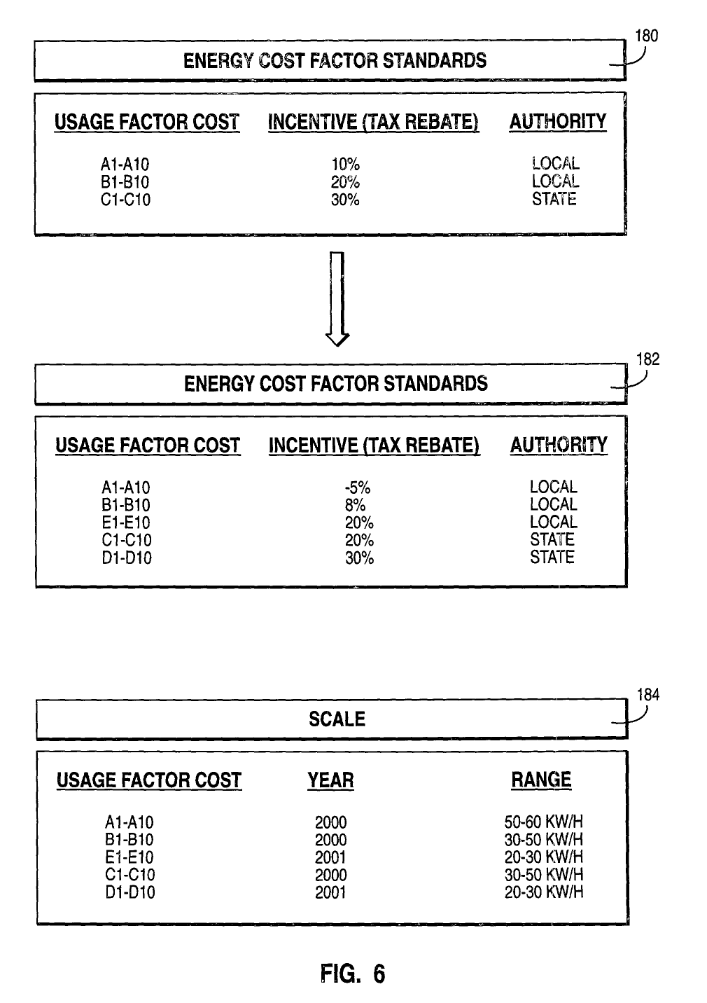

With reference now to FIG. 6, there is depicted a block diagram of energy factor cost standards in accordance with the method, system and program of the present invention. As illustrated, a first energy factor cost requirement table 180 includes multiple factor costs with associated incentives granted by multiple authorities.

In particular, the portion of the table 180 depicts usage factor costs with associated tax rebate incentives. In the example, usage factor costs are depicted as ranging from the values of A1-A10, B1-B10, and C1-C10. In alternate embodiments, alternate factor cost values may be utilized. Further, in alternate embodiments, the values may represent energy efficiency ratings for a product.

In addition, in the example, tax rebate incentives are depicted as tax rebates for the tax applied to the cost of the product. For example, if the usage factor cost is within the range of A1-A10, then a tax rebate of 10% of the cost of the product will be provided to the buyer.

Advantageously, a usage factor cost is assigned to a product component or packaging, as depicted in FIG. 5. If the usage factor cost is within the ranges specified in table 180, then an incentive is granted. The incentive may be granted by a particular authority. In the present example, tax rebate incentives are granted by local and state authorities. In alternate embodiments, alternate types of authorities may grant incentives.

A second energy factor cost requirement table 182 depicts adjustments to energy factor cost requirements, in response to updates in current energy efficiency technology. As illustrated, usage factor costs E1-E10 and D1-D10 have been added, where E1-E10 and D1-D10 represent the currently available energy efficiency cost ranges.

With the addition of new usage factor costs, the incentives for each set of usage factor costs is adjusted to reflect current energy efficiency technology. For example, if the usage factor cost is within the range of A1-A10, then a negative incentive is provided, rather than the 10% tax rebate that was previously provided for the range.

A scale table 184 illustrates the energy factor cost ranges associated with each range of usage factor costs. For example, a product that utilizes 50-60 Kwh of electricity will fall within the usage factor cost range of A1-A10.

As previously described, in addition to the incentives associated with each range of usage factor costs adjusting, the actual usage factor costs associated with a product may change over time according to increases or declines in energy efficiency.

With reference now to FIG. 7, there is depicted a high level logic flowchart of a process and program for requesting product incentives in accordance with the method, system, and program of the present invention. As illustrated, the process starts at block 200 and thereafter proceeds to block 202.

Block 202 depicts a determination as to whether a product incentive request is received. Preferably, a product incentive request may be received in response to a buyer purchasing a product, a buyer requesting to search available products, or the seller requesting the incentives for storage with the product identifier. If a product incentive request is not received, then the process iterates at block 202. If a product incentive request is received, then the process passes to block 204.

Block 204 depicts transmitting a product incentive request with a product identifier. In transmitting a product incentive request, the product identifier may first be utilized to determine energy factor costs that are then compared with energy factor cost requirements to determine an incentive.

Next, block 206 illustrates a determination as to whether or not a product incentive is received. If a product incentive is not received, then the process ends. If a product incentive is received, then the incentive is displayed to the buyer, as depicted in block 208, and the process passes to block 210.

Block 210 depicts a determination as to whether or not the incentive is automatic. An automatic incentive is one that may be directly applied to the cost of a product. If the incentive is not automatic, then the process passes to block 212. If the incentive is automatic, then the process passes to block 216.

Block 216 illustrates adjusting the product cost according to the incentive; and the process ends.

Block 212 illustrates a determination as to whether or not a buyer purchases the product. If a buyer does not purchase the product, then the process ends. If a buyer does purchase the product, then the process passes to block 214. Block 214 depicts transmitting the incentive to the buyer account; and the process ends. Where incentives include tax rebates, it is advantageous for such an incentive to be transferred to a buyer's account such that the buyer is provided with a record of accumulated tax rebates for a year.

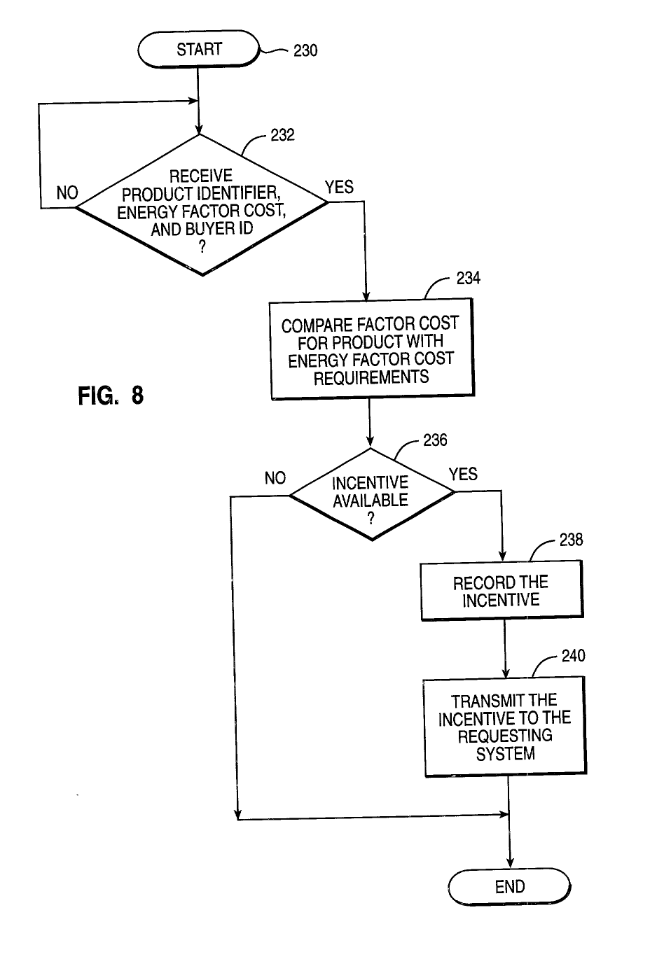

Referring now to FIG. 8, there is illustrated a high level logic flowchart of a process and program for determining product incentives for efficient products in accordance with the method, system, and program of the present invention. As depicted, the process starts at block 230 and thereafter proceeds to block 232.

Block 232 depicts a determination as to whether or not a product identifier, energy factor costs and a buyer or seller identifier are received. If the information is not received, then the process iterates at block 232. If the information is received, then the process passes to block 234.

Block 234 illustrates comparing the energy factor costs for the product with energy factor cost requirements. In comparing the energy factor costs for the product with energy factor cost requirements it can be determined whether an incentive is available or not. In particular, different authorities may provide different sets of energy factor cost requirements to determine the incentives provided by each of the different authorities.

Next, block 236 depicts a determination as to whether or not an incentive is available for the product. If an incentive is not available, then the process ends. If an incentive is available, then the process passes to block 227.

Block 227 illustrates recording the incentive according to a buyer or seller identifier and product identifier. Next, block 228 depicts transmitting the incentive in the form of a redeemable electronic payment to a requesting system; and the process ends.

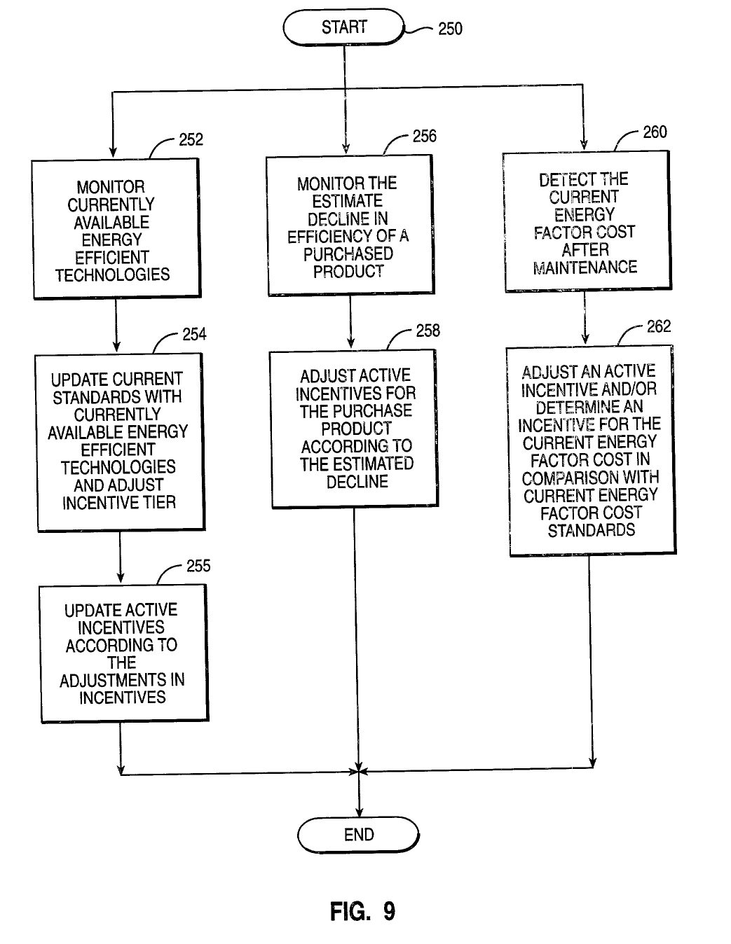

With reference now to FIG. 9, there is depicted a high level logic flowchart of a process and program for adjusting incentives for a product in accordance with the method, system, and program of the present invention. As illustrated, the process starts at block 250 and thereafter proceeds to blocks 252, 254, and 256. Preferably, multiple events that may occur in parallel may cause adjustments in incentives provided for energy efficient products.

Block 252 depicts monitoring the current energy efficiency technology available. Monitoring the current energy efficiency technology available may include monitoring adjustments to energy efficiency standards, monitoring actual product specifications, and monitoring energy efficient technology announcements. Next, block 254 illustrates adjusting standards to include current energy efficiency technology and tiering the incentives available according to levels of energy efficiency. Thereafter, block 256 depicts updating long-term incentives that are still active, according to the adjustments to incentives; and the process ends.

Block 256 illustrates monitoring the estimated decline in the efficiency of a purchased product. Monitoring the estimated decline in the efficiency of a purchased product may be performed by monitoring adjustments to energy cost factors and monitoring estimates for decline in energy efficiency published by product manufacturers or determined by an authority. Next, block 258 depicts adjusting active incentives according to the decline in energy efficiency; and the process ends.

Block 258 depicts detecting maintenance records according to product and consumer. Next, block 260 illustrates determining the current energy factor cost after maintenance of the product. Thereafter, block 262 depicts adjusting an active incentive and/or determining an incentive for the current energy factor cost in comparison with energy factor cost standards; and the process ends.

While the invention has been particularly shown and described with reference to a preferred embodiment, it will be understood by those skilled in the art that various changes in form and detail may be made therein without departing from the spirit and scope of the invention.

What is claimed is:

1. A method for promoting current energy efficiency technology, said method comprising the steps of:
maintaining a plurality of records of a plurality of active energy efficiency incentives each in association with one from among a plurality of products; and
in response to change in standing of one from among said plurality of products in relation to current energy efficiency technology, adjusting an associated one of said plurality of active energy efficiency incentives, such that purchase of said current energy efficiency technology is promoted.

2. The method for promoting current energy efficiency technology according to claim 1, said method further comprising the step of:
distributing a selection of said plurality of active energy efficiency incentives prior to purchase of an associated selection of said plurality of products, wherein said selection of said plurality of active energy efficiency incentives are rendered inactive after purchase.

3. The method for promoting current energy efficiency technology according to claim 1, said method further comprising the step of:
distributing a selection of said plurality of active energy efficiency incentives prior to purchase of an associated selection of said plurality of product, wherein said selection of said plurality of active energy efficiency incentives are transferred to a plurality of consumers after purchase and remain active for selected periods of time.

4. The method for promoting current energy efficiency technology according to claim 1, said method further comprising the step of:
distributing a selection of said plurality of active energy efficiency incentives after purchase of an associated selection of said plurality of products, wherein said selection of said plurality of activity energy efficiency incentives remain active after purchase for selected periods of time.

5. The method for promoting current energy efficiency technology according to claim 1, said method further comprising the steps of:
monitoring said current energy efficient technology available;
adjusting a set of energy efficiency standards to incorporate said current energy efficient technology; and
adjusting a plurality of incentive amounts associated with said set of energy efficiency standards in a tier scale according to said incorporation of said current energy efficient technology.

6. The method for promoting current energy efficiency technology according to claim 1, said method further comprising the steps of:
monitoring an estimated decline in efficiency of a product associated with at least one from among said plurality of active energy efficiency incentives; and
dynamically adjusting said at least one energy efficiency incentive according to said estimated decline in efficiency.

7. The method for promoting current energy efficiency technology according to claim 1, said method further comprising the steps of:
in response to receiving a record of maintenance performed on a particular product from among said plurality of products, detecting an estimated efficiency for maintenance of said particular product; and
dynamically adjusting a particular energy efficiency incentive associated with said particular product according to said estimated efficiency for maintenance.

8. The method for promoting current energy efficiency technology according to claim 1, said step of adjusting an associated one of said plurality of active energy efficiency incentives, further comprising the step of:
adjusting said associated one of said plurality of active energy efficiency incentive by performing at least one from among, increasing an amount, increasing a lifetime, adjusting an application, decreasing an amount, decreasing a lifetime, and penalizing continued use of said product.

9. A system for promoting current energy efficiency technology, said system comprising:
a server system comprising:
means for maintaining a plurality of records of a plurality of active energy efficiency incentives each in association with one from among a plurality of products; and
means for adjusting an associated one of said plurality of active energy efficiency incentives, in response to change in standing of one from among said plurality of products in relation to current energy efficiency technology.

10. The system for promoting current energy efficiency technology according to claim 9, said server system further comprising:
means for distributing a selection of said plurality of active energy efficiency incentives prior to purchase of an associated selection of said plurality of products, wherein said selection of said plurality of active energy efficiency incentives are rendered inactive after purchase.

11. The system for promoting current energy efficiency technology according to claim 9, said server system further comprising:
means for distributing a selection of said plurality of active energy efficiency incentives prior to purchase of an associated selection of said plurality of product, wherein said selection of said plurality of active energy efficiency incentives are transferred to a plurality of consumers after purchase and remain active for selected periods of time.

12. The system for promoting current energy efficiency technology according to claim 9, said server system further comprising:
means for distributing a selection of said plurality of active energy efficiency incentives after purchase of an associated selection of said plurality of products, wherein said selection of said plurality of activity energy efficiency incentives remain active after purchase for selected periods of time.

13. The system for promoting current energy efficiency technology according to claim 9, said server system further comprising:
means for monitoring said current energy efficient technology available;
means for adjusting a set of energy efficiency standards to incorporate said current energy efficient technology; and
means for adjusting a plurality of incentive amounts associated with said set of energy efficiency standards in a tier scale according to said incorporation of said current energy efficient technology.

14. The system for promoting current energy efficiency technology according to claim 9, said server system further comprising:
means for monitoring an estimated decline in efficiency of a product associated with at least one from among said plurality of active energy efficiency incentives; and
means for dynamically adjusting said at least one energy efficiency incentive according to said estimated decline in efficiency.

15. The system for promoting current energy efficiency technology according to claim 9, said server system further comprising:
means for detecting an estimated efficiency for maintenance of said particular product, in response to receiving a record of maintenance performed on a particular product from among said plurality of products; and
means for dynamically adjusting a particular energy efficiency incentive associated with said particular product according to said estimated efficiency for maintenance.

16. The system for promoting current energy efficiency technology according to claim 9, said means for adjusting an associated one of said plurality of active energy efficiency incentives, further comprising:
means for adjusting said associated one of said plurality of active energy efficiency incentive by performing at least one from among, increasing an amount, increasing a lifetime, adjusting an application, decreasing an amount, decreasing a lifetime, and penalizing continued use of said product.

17. A program for promoting current energy efficiency technology, residing on a computer usable medium having computer readable program code means, said program comprising:
means for maintaining a plurality of records of a plurality of active energy efficiency incentives each in association with one from among a plurality of products; and
means for adjusting an associated one of said plurality of active energy efficiency incentives.

18. The program for promoting current energy efficiency technology according to claim 17, said program further comprising:
means for controlling distribution of a selection of said plurality of active energy efficiency incentives prior to purchase of an associated selection of said plurality of products, wherein said selection of said plurality of active energy efficiency incentives are rendered inactive after purchase.

19. The program for promoting current energy efficiency technology according to claim 17, said program further comprising:
means for controlling distribution of a selection of said plurality of active energy efficiency incentives prior to purchase of an associated selection of said plurality of product, wherein said selection of said plurality of active energy efficiency incentives are transferred to a plurality of consumers after purchase and remain active for selected periods of time.

20. The program for promoting current energy efficiency technology according to claim 17, said program further comprising:
means for controlling distribution of a selection of said plurality of active energy efficiency incentives after purchase of an associated selection of said plurality of products, wherein said selection of said plurality of activity energy efficiency incentives remain active after purchase for selected periods of time.

21. The program for promoting current energy efficiency technology according to claim 17, said program further comprising:
means for monitoring said current energy efficient technology available;
means for adjusting a set of energy efficiency standards to incorporate said current energy efficient technology; and
means for adjusting a plurality of incentive amounts associated with said set of energy efficiency standards in a tier scale according to said incorporation of said current energy efficient technology.

22. The program for promoting current energy efficiency technology according to claim 17, said program further comprising:
means for monitoring an estimated decline in efficiency of a product associated with at least one from among said plurality of active energy efficiency incentives; and
means for dynamically adjusting said at least one energy efficiency incentive according to said estimated decline in efficiency.

23. The program for promoting current energy efficiency technology according to claim 17, said program further comprising:
means for detecting an estimated efficiency for maintenance of said particular product; and
means for dynamically adjusting a particular energy efficiency incentive associated with said particular product according to said estimated efficiency for maintenance.

24. The program for promoting current energy efficiency technology according to claim 17, said program further comprising:
means for adjusting said associated one of said plurality of active energy efficiency incentive by performing at least one from among, increasing an amount, increasing a lifetime, adjusting an application, decreasing an amount, decreasing a lifetime, and penalizing continued use of said product.
